(19) United States
(12) Patent Application Publication
(10) Pub. No.: US 2011/0187453 A1
(43) Pub. Date: Aug. 4, 2011

(54) Linearizer incorporating a phase shifter

(75) Inventors: Blythe Chadwick Deckman, Corona, CA (US); Michael Peter DeLisio, Monrovia, CA (US)

(73) Assignee: WAVESTREAM CORPORATION, San Dimas, CA (US)

(21) Appl. No.: 12/931,451

(22) Filed: Jan. 28, 2011

Related U.S. Application Data
(60) Provisional application No. 61/337,071, filed on Jan. 29, 2010.

(51) Int. Cl. H03F 1/26; H01P 5/12

(52) U.S. Cl. 330/149; 333/136; 333/137

(57) ABSTRACT

The present invention pertains to a pre-distorter linearizer that incorporates a balanced-to-unbalanced transmission line transition as a phase shifter to feed the linear and non-linear arms of the linearizer with signals of substantially the same amplitude and with a frequency-independent and substantially 180-degree phase difference. Preferably the balanced-to-unbalanced transmission line transition is a slotline-to-microstrip transition. Several alternatives are shown to enhance the bandwidth performance of the linearizer. Using a slotline-to-microstrip transition as a phase shifter provides for a very physically compact and inexpensive design. Furthermore, the flexibility of the slotline-to-microstrip architecture allows the linearizer to be easily integrated into systems that use both solid-state and vacuum-tube amplifiers.

### I. RELATED APPLICATIONS

This application claims priority to U.S. Provisional Patent Application No. 61/337,071, filed on Jan. 29, 2010. This application is also related to a PCT patent application filed concurrently herewith.

### II. FIELD OF THE INVENTION

The general field to which this invention relates is the amplification, generation, and control of microwave signals, which are used in telecommunications and radar/imaging systems. The invention improves the linear performance of a class of microwave amplifiers.

### III. BACKGROUND OF THE INVENTION

All physically realizable amplifiers add unwanted distortion to the signals they amplify. This is true of both solid-state and vacuum-tube amplifiers. As the level of an amplifier's drive signal increases, causing its output power to approach its maximum, distortion to the signal becomes increasingly worse. In practice, the usable power an amplifier can deliver is limited by the severity of the distortion it adds to its signals. There are two dimensions to an amplifier's signal distortion: amplitude modulation-to-amplitude modulation, and amplitude modulation-to-phase modulation.

The magnitude of an ideal amplifier's input-to-output transfer characteristic is a strictly linear relationship between input and output power as exemplified by the equation Pₒᵤₜ=G·Pᵢₙ, where Pₒᵤₜ is the output power, G is the amplifier's gain, and Pᵢₙ is the input power. With very low drive, real amplifiers very closely approximate the ideal amplifier's input-to-output transfer characteristic. As the drive level increases, however, the magnitude of an amplifier's gain drops, causing its input-to-output transfer characteristic to depart from the ideal linear relationship. This amplitude modulation-to-amplitude modulation (AM-AM) behavior is one source of distortion in all realizable amplifiers. FIG. 1 illustrates the difference between the magnitude of an ideal amplifier's input-to-output transfer characteristic to the magnitude of a real amplifier's input-to-output transfer characteristic. As shown in FIG. 1, as the input power increases, the magnitude of the in-to-output transfer characteristic of the real amplifier diverges from the magnitude of the in-to-output transfer characteristic of the ideal amplifier.

The phase of an ideal amplifier's input-to-output transfer characteristic is independent of signal amplitude. In practice, however, the phase of an amplifier varies as its output power increases. As shown in FIG. 2, the phase of a real amplifier changes as a function of its output power. As the output power increases, the phase of the real amplifier changes whereas the phase of the ideal amplifier remains constant. This amplitude modulation-to-phase modulation (AM-PM) is the second source of distortion in all realizable amplifiers.

To compensate for the distortion in real amplifiers, linearizers have been used extensively. One type of linearizer that may be used is a pre-distortion linearizer that uses a non-linear element, such as a diode or a transistor. Such a linearizer distorts the input signal to an amplifier with a reciprocal characteristic to the amplifier's, essentially neutralizing the distortion. A common architecture of pre-distortion linearizers involves two paths: a linear path and a non-linear path. An input signal is split between the two paths, processed by the two paths, and then recombined into a single signal that is sent directly to the input of the amplifier. The insertion gain and phase of the nonlinear path are functions of drive power; adding them to the linear path (with an appropriate phase adjustment) produces a net distortion characteristic that is substantially reciprocal to the amplifier's. In most cases, the appropriate phase adjustment is close to 180°, which implies a subtraction of the non-linear path from the linear path.

FIG. 3 illustrates how a pre-distortion linearizer functions. The non-linear path consists of an element (usually a diode or transistor) which saturates, meaning the output power no longer increases with increasing input drive power. By essentially subtracting this saturating non-linear path from the linear path, gain expansion can be achieved to properly pre-distort the signal. Note that the non-linear arm is represented by a vector pointing substantially away from the linear arm, which implies a subtraction of the two signals. At higher drive levels, the gain of the pre-distorter, represented by the length of the resultant vector relative to the length of the linear arm vector, increases. In this illustration, the phase of the pre-distorter, represented by the angle θ, decreases with increasing drive level. It is also possible to have a pre-distorter's phase increase with increasing drive level.

Critical to the performance of a two-path, single-diode pre-distorter is the dependence of the phase adjustment between the two paths on frequency. In practice, this phase shift needs to remain very close to 180 degrees over the pre-distorter's operating bandwidth in order to achieve the subtraction of the signals from the two arms. One approach is to use hybrid couplers, as shown in FIG. 4. In FIG. 4, a signal is input into the input terminal 402 of hybrid coupler 404. The hybrid coupler outputs two signals of equal amplitudes but with a 90-degree phase difference. One of these output signals feeds the linear arm 406 and the other output signal feeds non-linear arm 408. The outputs of linear arm 406 and non-linear arm 408 feed two inputs of a second hybrid coupler 410, which outputs a signal 412 that has a 180-degree phase shift from the input signal. The main drawback to this approach is that hybrid couplers are only useful over a relatively narrow bandwidth. Broader band hybrid couplers are also expensive and difficult to manufacture.

Another approach that is commonly used is to use lengths of transmission lines in order to achieve a phase shift, as shown in FIG. 5. In FIG. 5, a signal is input into the input terminal 502 of a power splitter 504. The two output arms of the power splitter 504 feed output signals to linear arm 506 and non-linear arm 508, with the two output signals having the same phase. The output of linear arm 506 feeds directly into one of the inputs of power combiner 512, but the output of the non-linear arm 510 feeds into the second input of power combiner 512 via a transmission line phase shifter 510 that shifts the phase of the output of the non-linear arm by 180 degrees. Power combiner 512 combines these two signals into output 514. However, using a transmission-line phase shifter often results in significant performance degradation because the phase shift provided by them is non-constant and dependent on the frequency of the signal. Finally, 180-degree hybrids fashioned with transmission lines suffer sufficient non-idealities that force a non-constant phase shift between their coupled arms.

### IV. SUMMARY OF THE INVENTION

The present invention pertains to a linearizer apparatus comprising: (a) a linearizer input section comprising balanced transmission line media; (b) a linear arm comprising a linear arm input section and a linear arm output section, the linear arm input section and the linear arm output section both comprising unbalanced transmission line media; (c) a non-linear arm comprising a non-linear arm input section and a non-linear arm output section, the non-linear arm input section and the non-linear arm output section both comprising unbalanced transmission line media; (d) a balanced-to-unbalanced transmission line transition comprising (i) a transition input section communicably connected to the linearizer input section, the transition input section comprising balanced transmission line media; and (ii) a transition output section with a first transition output arm and a second transition output arm, the transition output section comprising unbalanced transmission line media, the first transition output arm communicably connected to the linear arm input section to feed a first signal to the linear arm and the second transition output arm communicably connected to the non-linear arm input section to feed a second signal to the non-linear arm, wherein the first signal and the second signal are substantially 180 degree phase shifts of each other; (e) a power combiner comprising a first power combiner input section, a second power combiner input section, and a power combiner output section, the first power combiner input section and the second power combiner input section comprising unbalanced transmission line media, the first power combiner input section communicably connected to the linear arm output section and the second power combiner input section communicably connected to the non-linear arm output section; and (f) a linearizer output section communicably connected to the power combiner output section.

### V. BRIEF DESCRIPTION OF THE DRAWINGS

FIG. 1 is a chart that illustrates the differences between the magnitudes of the input-to-output transfer characteristics of an ideal amplifier and a real amplifier as a function of the input power.

FIG. 2 is a chart that illustrates how the phase of a real amplifier changes as a function of its output power. Shown here is an amplifier with an increasing phase response. Some amplifiers may have a decreasing phase response as well.

FIG. 3 is a series of illustrations that show how, in a two-path linearizer, a higher drive power increases the gain of a linearizer. In this illustration, the phase of the linearizer decreases, but it is possible to construct a two-path linearizer with increasing phase.

FIG. 4 is an. illustration of a common two-path linearizer architecture that uses hybrid couplers to achieve a 180-degree phase difference between the two paths.

FIG. 5 is an illustration of a common two-path linearizer architecture that uses a length of transmission line to achieve a 180-degree phase difference between the two paths.

FIG. 6 is an illustration of the linearizer of the preferred embodiment.

FIG. 7a is a magnified view of the slotline-to-microstrip transition that is part of the linearizer of the preferred embodiment.

FIG. 7b is an illustration of the bottom side of the slotline-to-microstrip transition that is part of the linearizer of the preferred embodiment.

FIG. 7c is an illustration of the top side of the slotline-to-microstrip transition that is part of the linearizer of the preferred embodiment.

FIG. 8 is an illustration of another embodiment of the present invention.

FIG. 9 is an illustration of a more general embodiment of the present invention where a balanced-to-unbalanced transmission line transition section is used.

FIG. 10 is a magnified view of a balanced-to-unbalanced transmission line transition section where the balanced transmission line is a twin-lead transmission line and where the unbalanced transmission line is a coaxial transmission line.

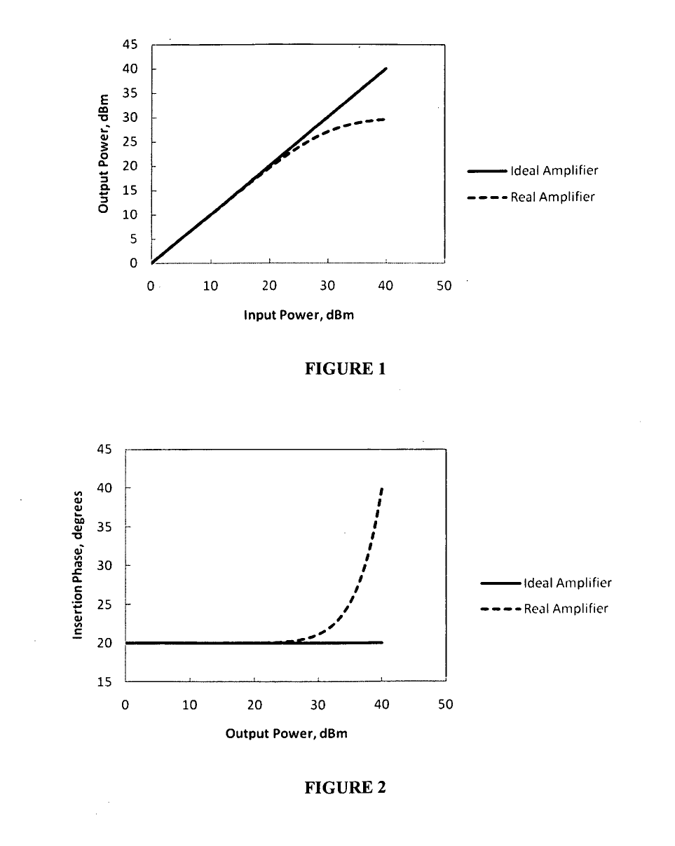

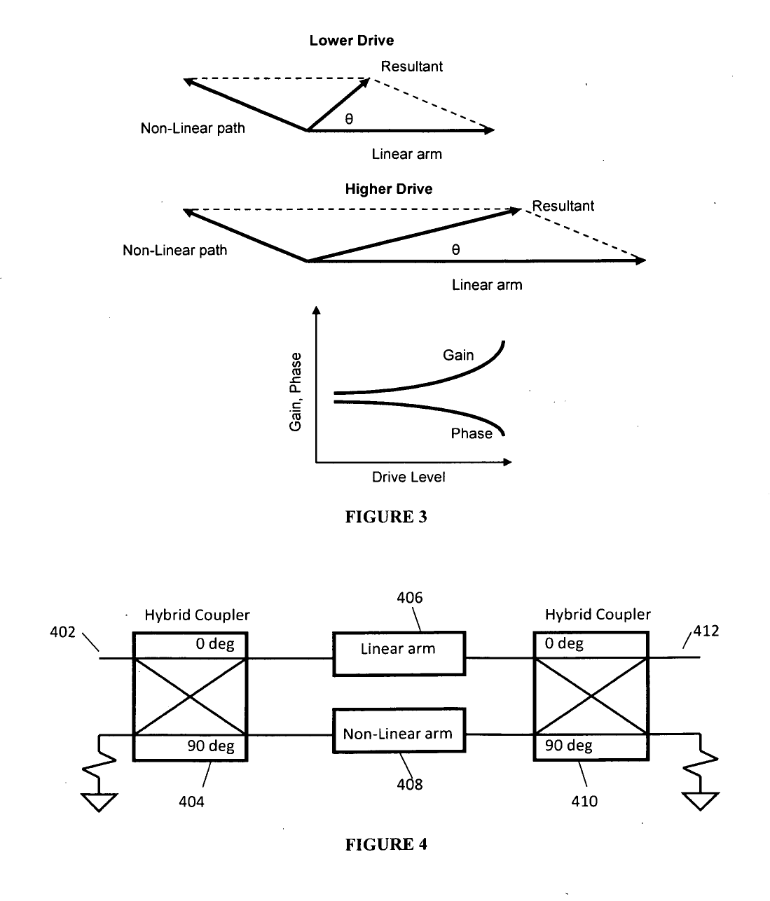

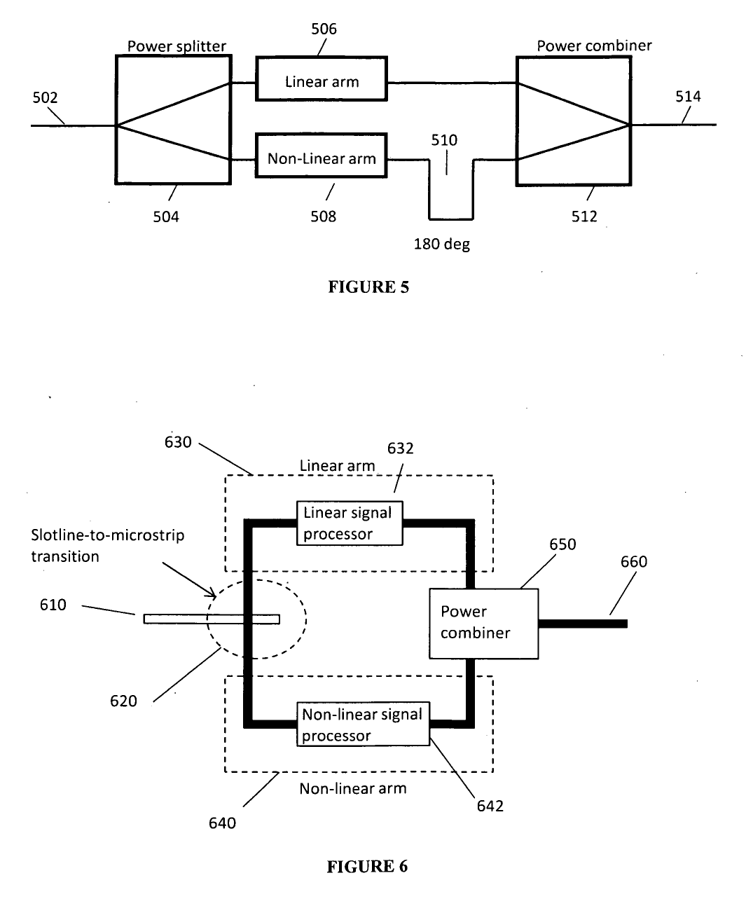

### VI. DETAILED DESCRIPTION OF THE PREFERRED EMBODIMENT

The preferred embodiment of the invention is illustrated by FIG. 6. As shown in FIG. 6, the present invention incorporates an input slotline section 610, a slotline-to-microstrip transition 620, a linear arm 630, a non-linear arm 640, a power combiner 650, and an output section 660.

In the preferred embodiment, the input slotline section 610 comprises an input slotline transmission line which carries the input signal. Although we specifically mention the transmission line architecture as slotline, it is understood that this function could be performed by any transmission line architecture that is closely related to, or derivative from the slotline transmission line architecture, such as grounded slotline and finline transmission line architectures. The input slotline section 610 communicably connects the slotline-to-microstrip transition 620.

The slotline-to-microstrip section 620 can be fabricated simply by etching a slot in an otherwise continuous metal plane on one side of a substrate, and patterning a microstrip line (oriented substantially perpendicularly to the slot) on the other side of the substrate to cross over the slot. From its physical symmetry, such a transition forces a purely differential mode between the two ends of the microstrip line, totally independent of frequency. This differential mode enforces the 180-degree phase difference between the two arms. Further, the amplitude balance between the two ends of the microstrip will be perfect, again due to the symmetry of the structure. This transition can be used to feed the two arms of the pre-distorter with a frequency-independent and substantially 180-degree phase shift to overcome the bandwidth limitation imposed by other phase shifter architectures.

Slotline-to-microstrip section 620 outputs to linear arm 630 and non-linear arm 640.

Linear arm 630 is the arm of the linearizer that processes a fraction of the signal delivered by the slotline-to-microstrip transition 620 without adding distortion to the signal. Linear arm 630 may incorporate a linear signal processor 632, which may include one or more of a phase shifter, time delay network, attenuator, amplifier, and a tuning structure to ensure sufficient performance over the linearizer's bandwidth of interest. Linear arm 630 may also include one or more sets of linear and non-linear arms. The linear arm 630 may also comprise media other than microstrip media provided that there is a suitable transition section that does not substantially affect the performance of the linearizer.

Non-linear arm 640 is the arm of the linearizer that processes a fraction of the signal delivered by the slotline-to-microstrip transition 620 and adds distortion to the signal. Distortion is added by the use of a non-linear signal processor 642. The non-linear signal processor 642 may include a diode, transistor, or any other non-linear device or combination of devices. It is also possible that the non-linear signal processor 642 may incorporate linear signal components, which may include one or more of a phase shifter, time delay network, attenuator, amplifier, and a tuning structure to ensure sufficient performance over the linearizer's bandwidth of interest. Non-linear arm 640 may also include one or more sets of linear and non-linear arms. The non-linear arm 640 may also comprise media other than microstrip media provided that there is a suitable transition section that does not substantially affect the performance of the linearizer.

The outputs of linear arm 630 and non-linear arm 640 are inputs into power combiner 650. One possible type of power combiner 650 is a Wilkinson-type microwave combiner. Power combiner 860 contains two or more input networks. Also, power combiner 650 may contain two or more input matching networks. These networks may incorporate transitions from microstrip, or some other transmission line media, to an arbitrary media wherein the power combiner section is fabricated. These input matching networks may also incorporate sufficient matching and tuning structures to ensure sufficient performance over the linearizer's bandwidth of interest. Power combiner 650 also includes a power combining section that combines the signals delivered to the input networks into a single signal which has a net distortion that is suitable to neutralize the amplifier's distortion over the bandwidth of interest. The transmission media of this section may also be arbitrary. Power combiner 650 may also include an output network that may include matching, tuning, and/or transition structures to deliver a suitable signal to the linearizer's output section 660.

The output section 660 may include matching and/or tuning structures as may be needed to ensure sufficient performance over the linearizer's bandwidth of interest. Output section 660 may also include attenuators or amplifiers to meet the system performance goals. The signal that is output from output section 660 may be input into an amplifier. The amplifier may be a solid state amplifier or a vacuum tube amplifier. The specifications of the linearizer of the preferred embodiment may be tailored so that the output signal of the linearizer is distorted with a substantially reciprocal characteristic to the amplifier's, essentially neutralizing the distortion.

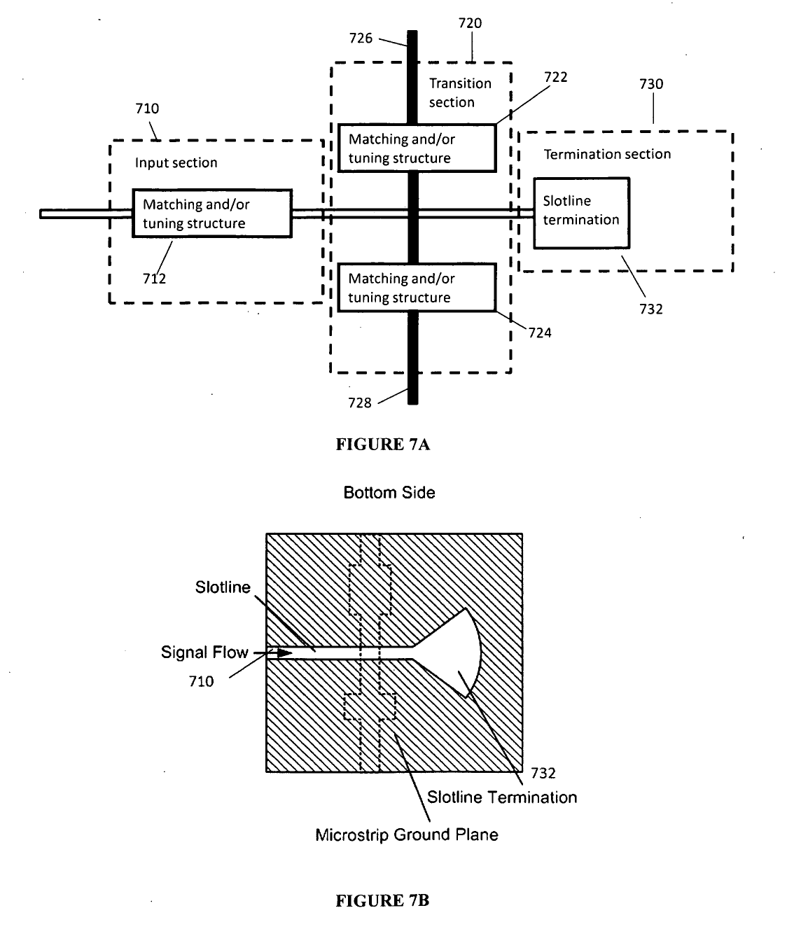

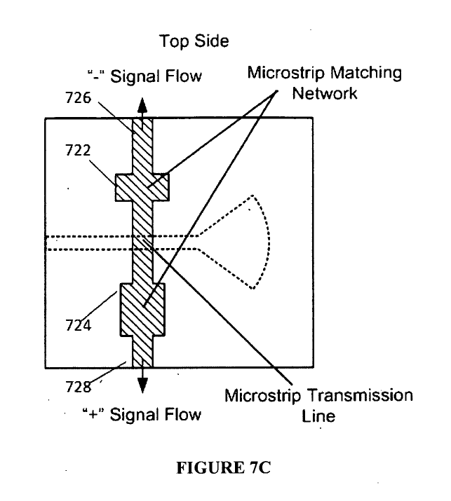

Slotline-to-microstrip section 620 is depicted in greater detail in FIG. 7a. Slotline-to-microstrip section 620 comprises an input section 710, a transition section 720, and optionally a termination section 730. Input section 710, which comprises a slotline transmission line media, may include matching and/or tuning structures 712 as may be needed to ensure sufficient performance over the linearizer's bandwidth of interest. Transition section 720, which comprises a microstrip transmission line media that has been patterned to cross over the slotline transmission line of input section 710, may also include matching and/or tuning structures 722 and 724 to ensure sufficient performance over the linearizer's bandwidth of interest. The output of transition section 720 is two microstrip transmission lines 726 and 728. Termination section 730, which comprises a slotline transmission line media, incorporates a slotline termination 732 suitable to ensure sufficient performance over the linearizer's bandwidth of interest. The purpose of this termination section 730 is to properly transfer energy from input section 710 to the two transmission lines 726 and 728 of transition section 720. If present, this termination could be a load, an open circuit, a radial stub, or a length of transmission line terminated with an appropriate load.

FIGS. 7b and 7c illustrate a more detailed example of how this slotline-to-microstrip transition 620 may be accomplished in practice. FIGS. 7b and 7c show the bottom and top sides, respectively, of a printed circuit board composed of a dielectric material suitable for use at microwave and radio frequencies. The bottom side of this board is substantially covered by a metal ground plane, with the exception of an etched slot, which defines the slotline transmission line of the input section 710. Also shown in FIG. 7b is a slotline termination section 732, shown in this case to be a radial stub, but which could also be a load, an open circuit, or a length of transmission line terminated with an appropriate load. The top side of this board, shown in FIG. 7c, is substantially devoid of metal cladding, with the exception of printed metal traces which define the microstrip transmission lines 726 and 728. Note that the microstrip transmission lines 726 and 728 are oriented substantially perpendicularly to the input slotline section 710 etched on the bottom side of the printed circuit board. Signals on the input slotline section 710 will excite signals on the microstrip transmission lines 726 and 728. The symmetry of this transition demands that the phases of the signals propagating on the microstrip transmission lines 726 and 728 will have substantially 180-degree phase differences, regardless of frequency. Symmetry also demands that the amplitude of the signals on the microstrip lines 726 and 728 will be substantially equal. Also shown in FIG. 7c are microstrip matching and/or tuning structures 77 and 724, which may or may not be necessary.

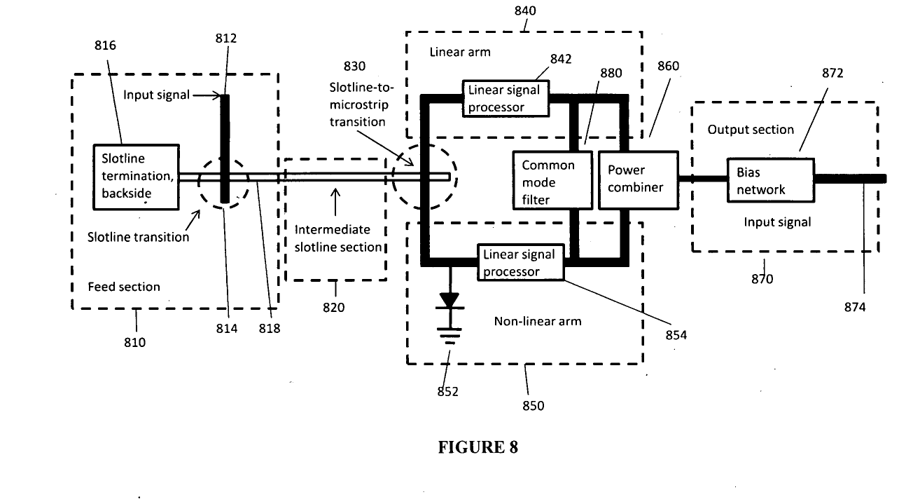

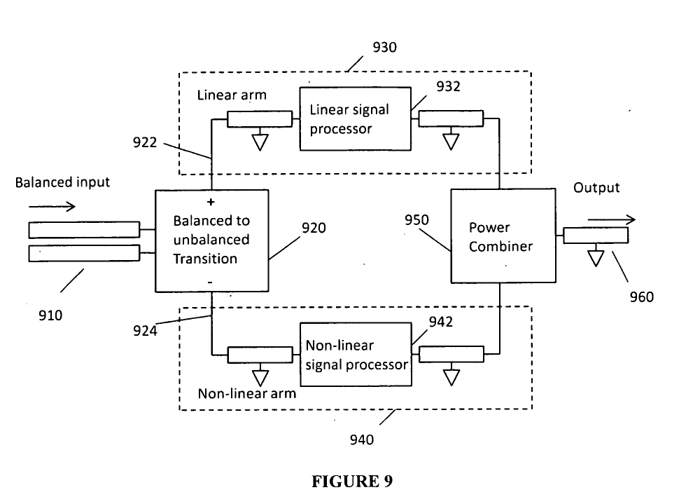

FIG. 8 contains another embodiment of the present invention. In this particular embodiment, there are two notable changes. First, it may be preferred to have a microstrip input, as opposed to a slotline input. Second, this embodiment includes a common-mode filter to improve the match seen looking into the output of the linearizer. The embodiment in FIG. 8 also incorporates a feed section 810, an intermediate slotline section 820, a slotline-to-microstrip transition 830, a linear arm 840, a non-linear arm 850, a power combiner 860, an output section 870, and a common mode filter 880.

The feed section 810 comprises an input section 812, a slotline transition 814, a slotline termination 816, and an output section 818. The input section 812, which carries the input signal, may be comprised of any type of transmission line media, including, but not limited to, a microstrip. The input section 812 will meet with the output section 818, which is preferably a slotline media, by slotline transition 814. Output section 818 communicably connects to intermediate section 820. Output section 818 may also include matching structures to ensure efficient energy transfer between the slotline transition 814 and the intermediate slotline section 820 over the bandwidth of interest. It should be noted that while transition 814 and output section 818 preferably relate to slotline transmission line media, other types of transmission line media can be used as well. Intermediate section 820 preferably comprises a slotline transmission line media. Alternatively, intermediate section 820 may be comprised of a different type of transmission line media with a transition to a slotline transmission line media. The purpose of intermediate section 820 is to convey energy delivered by the feed section 810 to the slotline-to-microstrip transition section 830.

Similar to the slotline-to-microstrip transition 620 of FIG. 6, the slotline-to-microstrip transition section 830 feeds linear arm 840 and non-linear arm 850 with signals that have substantially the same amplitude but that also have a frequency-independent and substantially 180-degree phase shift.

Linear arm 840 is the arm of the linearizer that processes a fraction of the signal delivered by the slotline-to-microstrip transition 830 without adding distortion to the signal. Linear arm 840 may incorporate a linear signal processor 842, which may include one or more of a phase shifter, time delay network, attenuator, amplifier, and a tuning structure to ensure sufficient performance over the linearizer's bandwidth of interest. Linear arm 840 may also include one or more sets of linear and non-linear arms. The linear arm 840 may also comprise media other than microstrip media provided that there is a suitable transition section that does not substantially affect the performance of the linearizer.

Non-linear arm 850 is the arm of the linearizer that processes a fraction of the signal delivered by the slotline-to-microstrip transition 830 and adds distortion to the signal. Distortion is added by the use of a non-linear network 852. The non-linear network 852 may be a diode, transistor, or any other non-linear device or combination of devices. Non-linear arm 860 may also incorporate a linear signal processor 854, which may include one or more of a phase shifter, time delay network, attenuator, amplifier, and a tuning structure to ensure sufficient performance over the linearizer's bandwidth of interest. Non-linear arm 850 may also include one or more sets of linear and non-linear arms. The non-linear arm 850 may also comprise media other than microstrip media provided that there is a suitable transition section that does not substantially affect the performance of the linearizer.

The outputs of linear arm 840 and non-linear arm 850 are inputs into power combiner 860. One possible type of power combiner 860 is a Wilkinson-type microwave combiner. Power combiner 860 contains two or more input networks. Also, power combiner 650 may contain two or more input matching networks. These networks may incorporate transitions from microstrip, or some other transmission line media, to an arbitrary media wherein the power combiner section is fabricated. These input matching networks may also incorporate sufficient matching and tuning structures to ensure sufficient performance over the linearizer's bandwidth of interest. Power combiner 860 also includes a power combining section that combines the signals delivered to the input networks into a single signal which has a net distortion that is suitable to neutralize the amplifier's distortion over the bandwidth of interest. The transmission media of this section may also be arbitrary. Power combiner 860 may also include an output network 870. The output section 870 may include matching and/or tuning structures as may be needed to ensure sufficient performance over the linearizer's bandwidth of interest. Output section 870 may also include attenuators or amplifiers to meet the system performance goals. Output section 870 may also include a bias network 872.

The signal that is output from output section 870 may be input into an amplifier. The amplifier may be a solid state amplifier or a vacuum tube amplifier. The specifications of the linearizer of the preferred embodiment may be tailored so that the output signal of the linearizer is distorted with a substantially reciprocal characteristic to the amplifier's, essentially neutralizing the distortion.

This embodiment also contains a common-mode filter 880. Common-mode filter 880 is communicably connected to the outputs of the linear arm 840 and the non-linear arm 850. The purpose of this common-mode filter is to terminate, or match, any signals on the linear arm 840 and the non-linear arm 850 that are in phase, or common mode. This filter will also serve to reduce the reflections that may be incident into the output section 870. In practice this filter may be constricted by incorporating a load resistor connected to an appropriate length of transmission line. Although this filter is shown as distinct from the power combiner 860, it is also possible that this function may be incorporated into the design of power combiner 860.

A more general embodiment of this invention is shown in FIG. 9. The frequency-independent 180-degree phase shift can not only be accomplished by the slotline-to-microstrip transition, but any number of balanced-to-unbalanced transmission line transition architectures. A balanced transmission line architecture is one where the two conductors carrying the signal are symmetric about some plane, and where the distribution of currents carried on one of the two conductors is matched by an equal but opposite current distribution on the other of the two conductors. Examples of balanced transmission lines include slotline, finline, grounded slotline, coplanar strips, grounded coplanar strips, coplanar waveguide, grounded coplanar waveguide, and twin lead transmission lines. In contrast, unbalanced transmission lines have no such symmetry and the two conductors often are quite different and have different current distributions. Unbalanced transmission lines often have one conductor referred to a common or “ground” potential. Examples of unbalanced transmission lines include microstrip, coaxial and stripline.

FIG. 9 illustrates a generalized embodiment of this invention incorporating a balanced input section 910, a balanced-to-unbalanced transition 920, a linear arm 930, a non-linear arm 940, a power combiner 950, and an unbalanced output section 960.

The balanced input section 910 conveys the input signal using a balanced transmission line architecture. The balanced input section 910 is communicatively connected to the balanced-to-unbalanced transition 920.

The balanced-to-unbalanced transition 920 transforms the two symmetric conductors of the balanced input section 910 to two output unbalanced transmission lines 922 and 924, which feed linear arm 930 and non-linear arm 940, respectively. From its physical symmetry, this transition forces a purely differential mode between the two output unbalanced transmission lines 922 and 924, totally independent of frequency. This differential mode enforces the substantially 180-degree phase difference between the two output unbalanced transmission lines 922 and 924. Further, the amplitude balance between the two output unbalanced transmission lines 922 and 924 will be substantially identical due to the symmetry of the structure. This transition can be used to feed the linear arm 930 and non-linear arm 940 with a frequency-independent and substantially 180-degree phase shift to overcome the bandwidth limitations imposed by other phase shifter architectures.

Linear arm 930 is the arm of the linearizer that processes a fraction of the signal delivered by the balanced-to-unbalanced transition 920 without adding distortion to the signal. Linear arm 930 may incorporate a linear signal processor 932, which may include one or more of a phase shifter, time delay network, attenuator, amplifier, and a tuning structure to ensure sufficient performance over the linearizer's bandwidth of interest. Linear arm 930 may also include one or more sets of linear and non-linear arms. The linear arm 930 may also comprise any transmission line media provided that there is a suitable transition section that does not substantially affect the performance of the linearizer.

Non-linear arm 940 is the arm of the linearizer that processes a fraction of the signal delivered by the balanced-to-unbalanced transition 920 and adds distortion to the signal. Distortion is added by the use of a non-linear signal processor 942. The non-linear signal processor 942 may include a diode, transistor, or any other non-linear device or combination of devices. It is also possible that the non-linear signal processor 942 may incorporate linear signal components, which may include one or more of a phase shifter, time delay network, attenuator, amplifier, and a tuning structure to ensure sufficient performance over the linearizer's bandwidth of interest. Non-linear arm 940 may also include one or more sets of linear and non-linear arms. The non-linear arm 940 may also comprise any transmission line media provided that there is a suitable transition section that does not substantially affect the performance of the linearizer.

The outputs of linear arm 930 and non-linear arm 940 are inputs into power combiner 950. One possible type of power combiner 950 is a Wilkinson-type microwave combiner. Power combiner 950 contains two or more input matching networks. These networks may incorporate transitions from any unbalanced transmission line media to an arbitrary transmission line media wherein the power combiner section is fabricated. These input matching networks may also incorporate sufficient matching and tuning structures to ensure sufficient performance over the linearizer's bandwidth of interest. Power combiner 950 also includes a power combining section that combines the signals delivered to the input networks into a single signal which has a net distortion that is suitable to neutralize the amplifier's distortion over the bandwidth of interest. The transmission media of this section may also be arbitrary. Power combiner 950 may also include an output network that may include matching, tuning, and/or transition structures to deliver a suitable signal to the linearizer's output section 960.

The output section 960 may include matching and/or tuning structures as may be needed to ensure sufficient performance over the linearizer's bandwidth of interest. Output section 960 may also include attenuators or amplifiers to meet the system performance goals. Output section 960 may be fabricated out of any transmission line media, either balanced or unbalanced. The signal that is output from output section 960 may be input into an amplifier. The amplifier may be a solid state amplifier or a vacuum tube amplifier. The specifications of the linearizer of the preferred embodiment may be tailored so that the output signal of the linearizer is distorted with a reciprocal characteristic to the amplifier's, essentially neutralizing the distortion.

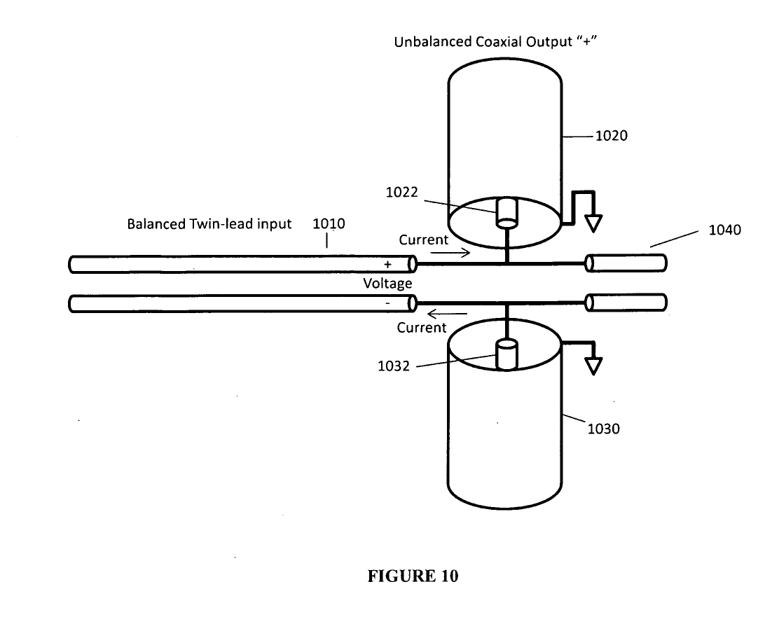

FIG. 10 shows one example of how this balanced-to-unbalanced transition 920 may be accomplished in practice. Here we show a transition specifically from balanced twin-lead transmission lines 1010 to unbalanced coaxial transmission lines 1020 and 1030. Other balanced-to-unbalanced transitions between other types of transmission lines are also possible. In this case, each of the conductors forming the symmetric balanced twin-lead input transmission line 1010 are connected to each of the center conductors 1022 and 1032 of a pair of unbalanced coaxial transmission lines 1020 and 1030, respectively. The voltages and currents on the input balanced twin-lead transmission line 1010 are shown to illustrate how the coupled signals on the unbalanced coaxial transmission lines 1020 and 1030 will be substantially 180-degrees out of phase, regardless of frequency. FIG. 10 also shows a balanced twin-lead transmission termination structure 1040, which in this case is shown to be a section of open-circuited transmission line. Again, we assert that other balanced termination structures may be used as well, such as a resistive load, an open circuit, a radial stub, or a length of transmission line terminated with an appropriate load.

It is to be understood that other embodiments may be utilized and structural and functional changes may be made without departing from the scope of the present invention. The foregoing descriptions of embodiments of the invention have been presented for the purposes of illustration and description. It is not intended to be exhaustive or to limit the invention to the precise forms disclosed. Accordingly, many modifications and variations are possible in light of the above teachings. It is therefore intended that the scope of the invention not be limited by this detailed description.

What is claimed is:

1. A linearizer apparatus, comprising:
(a) a linearizer input section comprising balanced transmission line media;
(b) a linear arm comprising a linear arm input section and a linear arm output section, the linear arm input section and the linear arm output section both comprising unbalanced transmission line media;
(c) a non-linear arm comprising a non-linear arm input section and a non-linear arm output section, the non-linear arm input section and the non-linear arm output section both comprising unbalanced transmission line media;
(d) a balanced-to-unbalanced transmission line transition comprising:
(i) a transition input section communicably connected to the linearizer input section, the transition input section comprising balanced transmission line media; and
(ii) a transition output section with a first transition output arm and a second transition output arm, the transition output section comprising unbalanced transmission line media, the first transition output arm communicably connected to the linear arm input section to feed a first signal to the linear arm and the second transition output arm communicably connected to the non-linear arm input section to feed a second signal to the non-linear arm, wherein the first signal and the second signal are substantially 180 degree phase shifts of each other;
(e) a power combiner comprising a first power combiner input section, a second power combiner input section, and a power combiner output section, the first power combiner input section and the second power combiner input section comprising unbalanced transmission line media, the first power combiner input section communicably connected to the linear arm output section and the second power combiner input section communicably connected to the non-linear arm output section; and
(f) a linearizer output section communicably connected to the power combiner output section.

2. The linearizer apparatus of claim 1, wherein the unbalanced transmission line media comprising the linear arm input section, linear arm output section, non-linear arm input section, non-linear arm output section, first power combiner input section, and second power combiner input section is microstrip transmission line media.

3. The linearizer apparatus of claim 1, wherein the unbalanced transmission line media comprising the linear arm input section, linear arm output section, non-linear arm input section, non-linear arm output section, first power combiner input section, and second power combiner input section is selected from the group consisting of coaxial and stripline transmission line media.

4. The linearizer apparatus of claim 1, wherein the balanced transmission line media comprising the linearizer input section is slotline transmission line media.

5. The linearizer apparatus of claim 1, wherein the balanced transmission line media comprising the linearizer input section is selected from the group consisting of finline, grounded slotline, coplanar strips, grounded coplanar strips, coplanar waveguide, grounded coplanar waveguide, and twin lead transmission line media.

6. The linearizer apparatus of claim 1, wherein the linear arm comprises a sub-linear arm and a sub-non-linear arm.

7. The linearizer apparatus of claim 1, wherein the non-linear arm comprises a sub-linear arm and a sub-non-linear arm.

8. The linearizer apparatus of claim 1, wherein the linear arm further comprises a linear signal processor.

9. The linearizer of claim 8, wherein the linear signal processor contains one or more devices selected from the group consisting of a phase shifter, an attenuator, an amplifier, a time delay structure, and a tuning structure.

10. The linearizer apparatus of claim 1, wherein the non-linear arm further comprises a non-linear signal processor.

11. The linearizer apparatus of claim 1, wherein the non-linear arm further comprises a linear signal processor.

12. The linearizer of claim 10, wherein the non-linear signal processor contains one or more devices selected from the group consisting of a diode and a transistor.

13. The linearizer of claim 1, wherein the balanced-to-unbalanced transmission line transition further comprises a balanced termination section.

14. The linearizer of claim 1, wherein the first transition output arm comprises a matching network.

15. The linearizer of claim 1, wherein the second transition output arm comprises a matching network.

16. The linearizer of claim 1 further comprising a common mode filter communicably connected to the linear arm output section and the non-linear arm output section.

17. The linearizer of claim 1 wherein the linearizer apparatus is used to improve the linearity of a microwave amplifier.

18. The linearizer of claim 17 wherein the microwave amplifier is a vacuum-tube amplifier.

19. The linearizer of claim 17 wherein the microwave amplifier is a solid-state amplifier.

20. A method of using a linearizer, comprising:
(a) applying a linearizer input signal from a linearizer input section to a transition input section of a balanced-to-unbalanced transmission line transition, the transition input section comprising balanced transmission line media, the balanced-to-unbalanced transmission line transition further comprising a transition output section with a first transition output arm which outputs a first signal and a second transition output arm which outputs a second signal, the transition output section comprising unbalanced transmission line media, wherein the first signal and the second signal are substantially 180 degree phase shifts of each other;
(b) applying the first signal to a linear arm input section of a linear arm of the linearizer, the linear arm further comprising a linear arm output section, the linear arm input section and linear arm output section both comprising unbalanced transmission line media, the linear arm output section outputting a third signal;
(c) applying the second signal to a non-linear arm input section of a non-linear arm of the linearizer, the non-linear arm further comprising a non-linear arm output section, the non-linear arm input section and non-linear arm output section both comprising unbalanced transmission line media, the non-linear arm output section outputting a fourth signal;
(d) applying the third signal to a first power combiner input section and the fourth signal to a second power combiner input section of a power combiner, the first power combiner input section and the second power combiner input section comprising unbalanced transmission line media, the power combiner further comprising a power combiner output section outputting a fifth signal; and
(e) applying the fifth signal to a linearizer output section, the linearizer output section outputting a linearizer output signal.

21. The method of claim 20, wherein the unbalanced transmission line media comprising the linear arm input section, linear arm output section, non-linear arm input section, non-linear arm output section, first power combiner input section, and second power combiner input section is microstrip transmission line media.

22. The method of claim 20, wherein the unbalanced transmission line media comprising the linear arm input section, linear arm output section, non-linear arm input section, non-linear arm output section, first power combiner input section, and second power combiner input section is selected from the group consisting of coaxial and stripline transmission line media.

23. The method of claim 20, wherein the balanced transmission line media comprising the linearizer input section is slotline transmission line media.

24. The method of claim 20, wherein the balanced transmission line media comprising the linearizer input section is selected from the group consisting of finline, grounded slotline, coplanar strips, grounded coplanar strips, coplanar waveguide, grounded coplanar waveguide, and twin lead transmission line media.

25. The method of claim 20, wherein the linearizer further comprises a common mode filter communicably connected to the linear arm output section and the non-linear arm output section.

26. A linearizer apparatus, comprising:
(a) a linearizer slotline input section;
(b) a linear arm comprising a linear arm microstrip input section and a linear arm microstrip output section;
(c) a non-linear arm comprising a non-linear arm microstrip input section and a non-linear arm microstrip output section;
(d) a slotline-to-microstrip transition comprising:
(i) a transition slotline input section communicably connected to the linearizer slotline input section; and
(ii) a transition microstrip output section with a first transition microstrip output arm and a second transition microstrip output arm, the first transition microstrip output arm communicably connected to the linear arm microstrip input section to feed a first signal to the linear arm and the second transition microstrip output arm communicably connected to the non-linear arm microstrip input section to feed a second signal to the non-linear arm, wherein the first signal and the second signal are substantially 180 degree phase shifts of each other;
(e) a power combiner comprising a first power combiner microstrip input section, a second power combiner microstrip input section, and a power combiner output section, the first power combiner input section communicably connected to the linear arm microstrip output section and the second power combiner input section communicably connected to the non-linear arm microstrip output section; and
(f) a linearizer output section communicably connected to the power combiner output section.

27. The linearizer of claim 26 further comprising a common mode filter communicably connected to the linear arm output section and the non-linear arm output section.

28. A method of using a linearizer, comprising:
(a) applying a linearizer input signal from a linearizer slotline input section to a transition slotline input section of a slotline-to-microstrip transition, the slotline-to-microstrip transition further comprising a transition output section with a first transition microstrip output arm which outputs a first signal and a second transition microstrip output arm which outputs a second signal, wherein the first signal and the second signal are substantially 180 degree phase shifts of each other;
(b) applying the first signal to a linear arm microstrip input section of a linear arm of the linearizer, the linear arm further comprising a linear arm microstrip output section, the linear arm output section outputting a third signal;
(c) applying the second signal to a non-linear arm microstrip input section of a non-linear arm of the linearizer, the non-linear arm further comprising a non-linear arm microstrip output section, the non-linear arm output section outputting a fourth signal;
(d) applying the third signal to a first power combiner microstrip input section and the fourth signal to a second power combiner microstrip input section of a power combiner; the power combiner further comprising a power combiner output section outputting a fifth signal; and
(e) applying the fifth signal to a linearizer output section, the linearizer output section outputting a linearizer output signal.

29. The method of claim 28, wherein the linearizer further comprising a common mode filter communicably connected to the linear arm output section and the non-linear arm output section.
